(19) United States
(12) Patent Application Publication
(10) Pub. No.: US 2026/0260691 A1
(43) Pub. Date: Sep. 3, 2026

(54) UPDATING EYE-MONITOR RELATED PARAMETERS FOR A MEMORY SYSTEM

(71) Applicant: Micron Technology, Inc., Boise, ID (US)

(72) Inventors: Chaohui Liu, Shanghai (CN); Ting Qiu, Shanghai (CN)

(21) Appl. No.: 19/543,608

(22) Filed: Feb. 18, 2026

Related U.S. Application Data
(60) Provisional application No. 63/764,974, filed on Feb. 28, 2025.

(51) Int. Cl. G11C 16/26; G11C 16/20; G11C 16/32

(52) U.S. Cl. CPC G11C 16/26; G11C 16/20; G11C 16/32

(57) ABSTRACT

Methods, systems, and devices for updating eye-monitor related parameters for a memory system are described. The memory system may receive, from a host system and while operating according to a first signaling mode, a command to update a parameter related to an eye-monitor function of the memory system. In response to the command, the memory system may store an updated value of the parameter in memory of the memory system and update, while operating according to a second signaling mode, the parameter with the updated value. Further, the memory system may perform the eye-monitor function in accordance with the updated parameter.

### CROSS REFERENCE

The present Application for Patent claims priority to U.S. Patent Application No. 63/764,974 by Liu et al., entitled “UPDATING EYE-MONITOR RELATED PARAMETERS FOR A MEMORY SYSTEM,” filed February 28, 2025, which is assigned to the assignee hereof, and which is expressly incorporated by reference in its entirety herein.

### TECHNICAL FIELD

The following relates to one or more systems for memory, including updating eye-monitor related parameters for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports updating eye-monitor related parameters for a memory system in accordance with examples as disclosed herein.

FIG. 2 shows an example of a system that supports updating eye-monitor related parameters for a memory system in accordance with examples as disclosed herein.

FIG. 3 shows an example of a flow diagram that supports updating eye-monitor related parameters for a memory system in accordance with examples as disclosed herein.

FIG. 4 shows a block diagram of a memory system that supports updating eye-monitor related parameters for a memory system in accordance with examples as disclosed herein.

FIG. 5 shows a flowchart illustrating a method or methods that support updating eye-monitor related parameters for a memory system in accordance with examples as disclosed herein.

### DETAILED DESCRIPTION

A memory system may support eye-monitor functionality. Eye-monitoring may be described as a feature that allows the memory system to visualize signal health. To support the eye-monitor functionality, the memory system may store eye-monitor related parameters such as direct current (DC) gain. To improve the eye-monitor functionality, the host system may update the parameters. To update the parameters, the host system may transmit, while the memory system is under pulse width modulation (PWM) mode, a command to update the parameters and, while under the PWM mode, the memory system, may update the parameters to an updated value. However, in a test environment, there may be no way to force the PWM mode and therefore, no way to update or evaluate the parameters.

The method as disclosed herein provides an alternative way to modify eye-monitor related parameters. In some examples, the memory system may receive, from the host system and while operating according to a first signaling mode (e.g., HS mode), a command to update a parameter related to an eye-monitor function of the memory system. In response to the command, the memory system may store an updated value of the parameter in memory of the memory system and update, while operating according to a second signaling mode (e.g., PWM mode), the parameter with the updated value. Further, the memory system may perform the eye-monitor function in accordance with the updated parameter. Using these methods, eye-monitor related parameters may be updated and evaluated in a variety of scenarios including during testing.

In addition to applicability in memory systems as described herein, techniques for updating eye-monitor related parameters for a memory system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by allowing the memory system to modify eye-monitor related parameters, which may improve eye-monitor functionality, among other benefits.

Features of the disclosure are illustrated and described in the context of systems, devices, and circuits. Features of the disclosure are further illustrated and described in the context of a flow diagram and a flowchart.

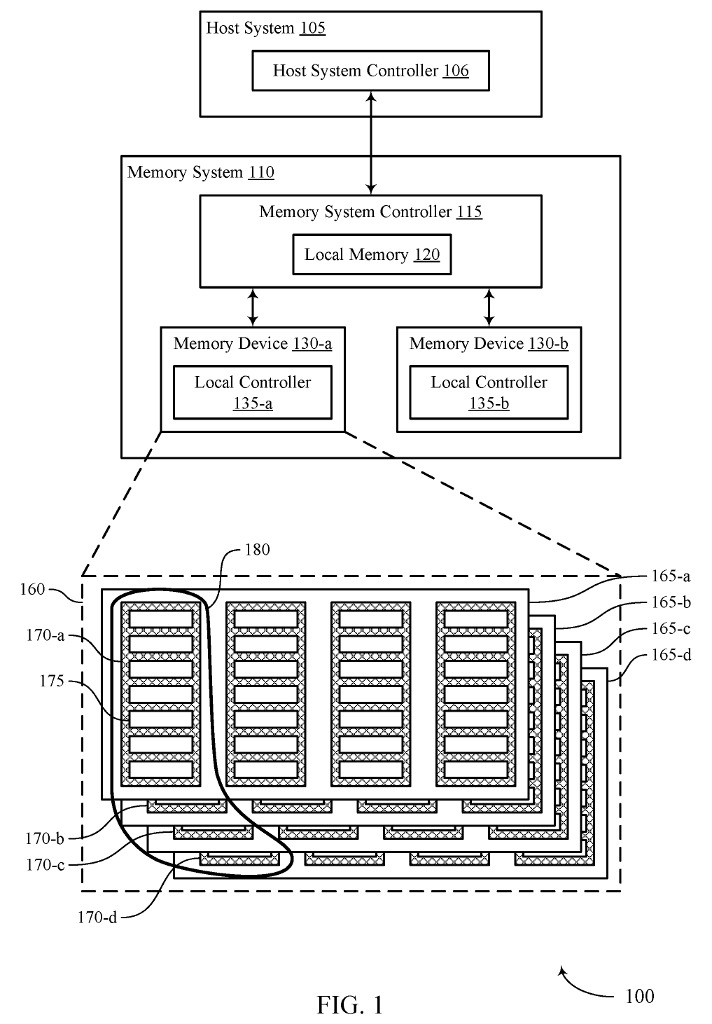

FIG. 1 shows an example of a system 100 that supports updating eye-monitor related parameters for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may support modification of eye-monitor related parameters. In some examples, the memory system 110 may receive, from the host system 105 and while operating according to a first signaling mode, a command to update a parameter related to an eye-monitor function of the memory system 110. In response to the command, the memory system 110 may store an updated value of the parameter in memory of the memory system and update, while operating according to a second signaling mode, the parameter with the updated value. Further, the memory system 110 may perform the eye-monitor function in accordance with the parameters. Using these methods, eye-monitor related parameters may be updated and evaluated in a variety of scenarios including during testing.

The system 100 may include any quantity of non-transitory computer readable media that support updating eye-monitor related parameters for a memory system. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

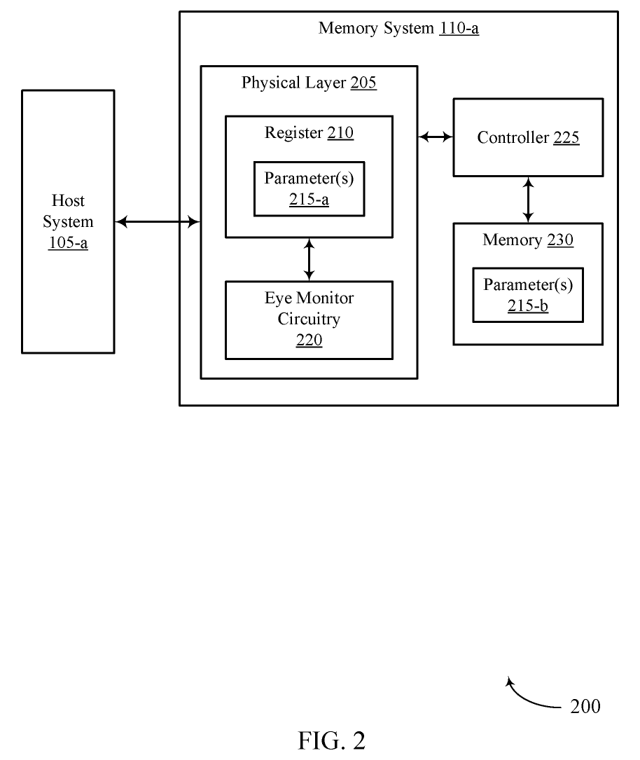

FIG. 2 shows an example of a system 200 that supports updating eye-monitor related parameters for a memory system in accordance with examples as disclosed herein. In some examples, the system 200 may implement aspects of the system 100. For example, the system 200 may include a host system 105-a and a memory system 110-a which may be examples of the host system 105 and the memory system 110, respectively, as described with reference to FIG. 1.

The memory system 110-a (e.g., a UFS memory device) may operate in accordance to a protocol stack (e.g., a UniPro protocol stack). The protocol stack may include multiple protocol layers that each provide a different function. The lowest protocol layer of the protocol stack may include a physical layer 205. The physical layer 205 may be responsible for communicating data to and from the memory system 110-a via a physical medium such as wires. In some examples, the physical layer 205 may support different speed modes. For example, the physical layer 205 may support a low speed (LS) mode (e.g., a pulse width modulation (PWM) mode) which may allow for transmission in a Mbps speed range and a high speed (HS) mode which may allow for transmission in a Gbps speed range. Further, the HS mode may include a default gear (HS-G1) and four operation gears (HS-G2, HS-G3, HS-G4, and HS-G5) at increment 2x higher rates. The memory system 110-a may enter or exit the different speed modes depending on an operating state of the memory system 110-a. For example, the memory system 110-a may enter PWM mode during a bootup phase of the memory system 110-a.

In some examples, the memory system 110-a may also support eye-monitor functions at the physical layer 205. Eye-monitor functions may allow the memory system 110-a to visualize signal health. Using eye-monitor circuitry 220, the memory system 110-a may superimpose rising and falling edges of a bitstream in a time domain to generate an eye diagram. From this eye diagram, the memory system 110-a or the host system 105-a may determine the following signal health information: timing jitter, signal level variance, average rise/fall times, average symbol duration, bit error rate (BER), etc. To support eye-monitor functions, the memory system 110-a may include one or more registers 210 at the physical layer 205 configured to store one or more eye-monitor related parameters 215. Examples of the parameters 215 may include a direct current (DC) gain, continuous time linear equalization (CTLE) peak, decision feedback equalization (DFE) offset (refer to H1_DEFAULT in GF CSRs), and receiver (Rx) clock and data recovery (CDR) (refer to TRACK_GAIN in GF CSRs).

To improve eye-monitor functions over time, the memory system 110-a may update one or more of the parameters 215. To update the one or more parameters 215, the memory system 110-a may receive, while operating according to PWM mode, a command (e.g., vender specific (VU) command) to update the one or more parameters 215 and the memory system 110-a may configure the one or more registers 210 with the updated one or more parameters 215. If the memory system 110-a transitions from the PWM mode to HS mode, the memory system 110-a may perform eye monitor functions in accordance with the one or more updated parameters 215. More specifically, the one or more updated parameters 215 may take effect if the memory system 110-a enters HS-G4 or HS-G5 with adapt on.

However, in some scenarios (e.g., during testing), the host system 105-a may be unable to force the memory system 110-a to enter PWM mode in order to send the command to update the one or more parameters 215. Instead, the host system 105-a may only transition to the memory system 110-a into the PWM mode during bootup stages. Thus, in some scenarios, the host system 105-a may be unable update the one or more parameters 215 as needed.

Accordingly, described herein is an alternative method to modify the one or more eye-monitor related parameters 215. As shown in FIG. 2, one or more registers 210 at the physical layer 205 of the memory system 110-a may store one or more eye-monitor related parameters 215-a. In some examples, some change at the host system 105-a or the memory system 110-a may prompt the host system 105-a to update the one or more parameters 215-a to be one or more parameters 215-b. To enact such change, the host system 105-a may transmit, while the memory system 110-a is in HS mode, a command (e.g., a VU command) to update the one or more parameters 215-a to be the one or more parameters 215-b. In some examples, the command may also include an indication of the one or more parameters 215-b (or a value of the one or more parameters 215-b).

Upon receiving the command from the host system 105-a, the memory system 110-a may store the one or more parameters 215-b in memory 230 (e.g., via a controller 225). In some examples, the memory 230 may be an example of non-volatile memory. Later, the memory system 110-a may transition from the HS mode to the PWM mode. For example, the memory system 110-a may enter the PWM mode during the bootup phase after the system 200 restarts. While in the PWM mode, the memory system 110-a may retrieve (or read) the one or more parameters 215-b from the memory (e.g., via the controller 225) and update the one or more registers 210 with the one or more parameters 215-b.

After this, the memory system 110-a may transition from the PWM mode to the HS mode. While in the HS mode, the memory system 110-a may perform eye monitor functions in accordance with the one or more parameters 215-b and dump eye monitor data to compare. In some examples, the one or more updated parameters 215-b may take effect when the memory system 110-a enters HS-G4 or HS-G5 with adapt on.

In some examples, the host system 105-a may quit a current eye-monitor function (e.g., refrain from performing the eye monitor function in accordance with the one or more parameters 215-b) and return to a default eye-monitor function. To quit the current eye-monitor function, the host system 105-a may transmit, while the memory system 110-a is under HS mode, a second command to reset the one or more parameters 215 stored in the one or more registers 210 to a respective default value. In some examples, the second command may indicate the reset of the one or more parameters 215 by including an indication of a reset value (e.g., 0) for each of the one or more parameters 215 that the host system 105-a intends to reset.

In response to receiving the second command, the memory system 110-a may store the one or more reset values in the memory 230. Later, the host system 105-a may restart the system 200 and the memory system 110-a may transition to PWM mode. In PWM mode, the memory system 110-a retrieve the one or more reset values from the memory 230 and reset the corresponding one or more parameters 215 in the one or more registers 210 with the respective default value.

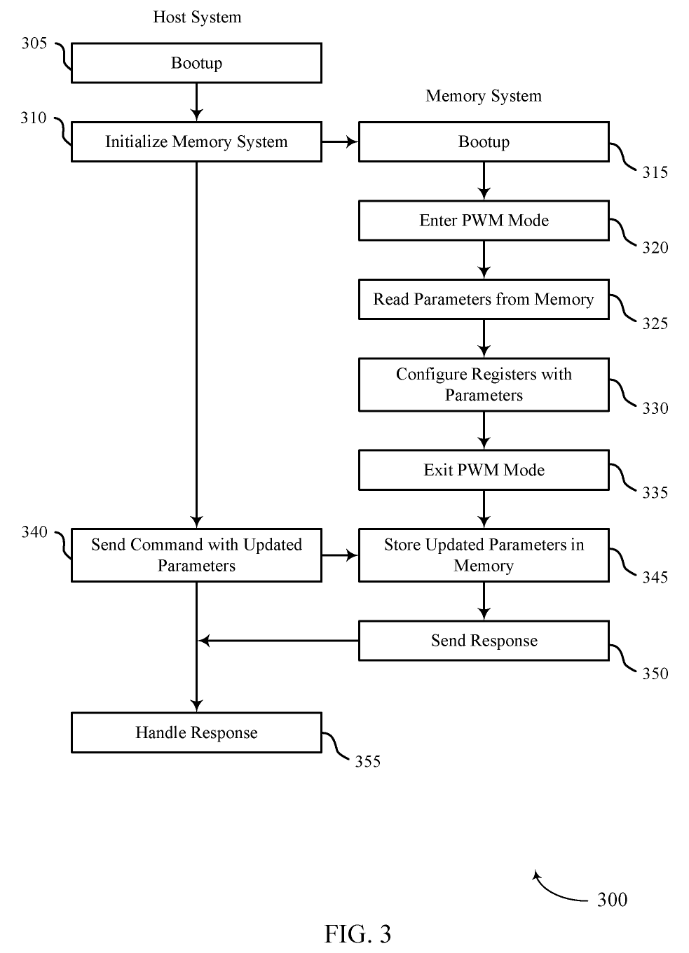

FIG. 3 shows an example of a flow diagram 300 that supports updating eye-monitor related parameters for a memory system in accordance with examples as disclosed herein.

For example, steps 305, 310, 340, and 355 of the flow diagram 300 may be implemented by a host system which may be an example of the host system 105 as described with reference to FIGS. 1 and 2. Further, steps 315, 320, 325, 330, 335, 345, and 350 of the flow diagram 300 may be implemented by a memory system which may be an example of the memory system 110 as described with reference to FIGS. 1 and 2.

At 305, a boot procedure may be performed. For example, the host system may perform the boot procedure.

At 310, the memory system may be initialized. For example, the host system may initialize the memory system.

At 315, a second boot procedure may be performed. For example, the memory system may perform the second boot procedure.

At 320, a first signaling mode may be entered. For example, the memory system may enter the first signaling mode (e.g., a PWM mode) as part of the boot procedure.

At 325, a parameter may be read. For example, the memory system may read a first value of the parameter related to an eye-monitor function of the memory system from memory (e.g., non-volatile memory) of the memory system. The parameter may include a DC gain, a CTLP peak, a DFE offset, or Rx CDR. In some examples, the first value of the parameter may be different than a second value of the parameter stored in a register at the physical layer of the memory system. That is, the first value of the parameter stored in the memory may be an updated value.

In some examples, the first value of the parameter may include a reset value (or a value of one). The reset value may indicate to reset the second value of the parameter stored in the register at the physical layer to a default value (or a third value).

At 330, a register may be configured with the parameter, For example, the memory system may configure the register in response to reading the memory. In some examples, the memory system may configure the register such that the parameter stored at the register has the first value. In another example, the memory system may configure the register such that the parameter stored at the register has the default value.

At 335, the first signaling mode may be exited. For example, the memory system may exit the first signaling mode and enter a second signaling mode (e.g., a HS mode).

At 340, a command may be transmitted. For example, the host system may transmit the command (e.g., a VU command) to update the parameter. In some examples, the command may include an updated value of the parameter (e.g., a fourth value different than the second value or the default value)

At 345, the updated parameter may be stored. For example, the memory system may store the updated value of the parameter in the memory in response to the command.

At 350, a response may be sent. For example, the memory system may send the response to the host system verifying that the updated value of the parameter was stored in the memory in response to storing the updated value of the parameter in the memory.

At 355, a system restart is performed. For example, the host system may perform the system restart.

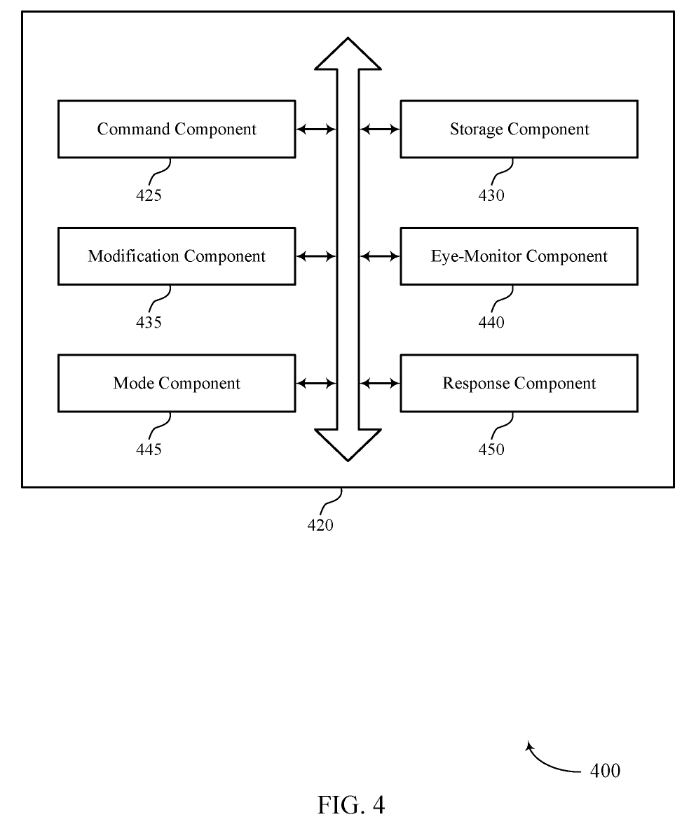

FIG. 4 shows a block diagram 400 of a memory system 420 that supports updating eye-monitor related parameters for a memory system in accordance with examples as disclosed herein. The memory system 420 may be an example of aspects of a memory system as described with reference to FIGS. 1 through 3. The memory system 420, or various components thereof, may be an example of means for performing various aspects of updating eye-monitor related parameters for a memory system as described herein. For example, the memory system 420 may include a command component 425, a storage component 430, a modification component 435, an eye-monitor component 440, a mode component 445, a response component 450, or any combination thereof. Each of these components, or components of subcomponents thereof (e.g., one or more processors, one or more memories), may communicate, directly or indirectly, with one another (e.g., via one or more buses).

The command component 425 may be configured as or otherwise support a means for receiving, while operating the memory system according to a first signaling mode, a command to update a parameter related to an eye-monitor function of the memory system. The storage component 430 may be configured as or otherwise support a means for storing an updated value of the parameter in memory of the memory system in response to the command. The modification component 435 may be configured as or otherwise support a means for updating, while operating the memory system according to a second signaling mode, the parameter with the updated value in response to reading the updated value from the memory. The eye-monitor component 440 may be configured as or otherwise support a means for performing, while operating according to the first signaling mode, the eye-monitor function in accordance with the parameter.

In some examples, the command component 425 may be configured as or otherwise support a means for receiving, after performing the eye-monitor function and while operating the memory system according to the first signaling mode, a second command to reset the parameter related to the eye-monitor function of the memory system to a first value from the updated value.

In some examples, the storage component 430 may be configured as or otherwise support a means for storing a reset value of the parameter in the memory of the memory system in response to the second command.

In some examples, the modification component 435 may be configured as or otherwise support a means for updating, while operating the memory system according to the second signaling mode, the parameter with the first value in response to reading the reset value from the memory. In some examples, the reset value includes a value of zero.

In some examples, the mode component 445 may be configured as or otherwise support a means for entering the second signaling mode as part of a boot procedure at the memory system, where the parameter is updated in response to entering the second signaling mode. In some examples, the mode component 445 may be configured as or otherwise support a means for exiting the second signaling mode, where the command is received in response to exiting the second signaling mode.

In some examples, the response component 450 may be configured as or otherwise support a means for transmitting a message verifying that the updated value of the parameter was stored in the memory of the memory system in response to storing the updated value of the parameter in the memory of the memory system. In some examples, the first signaling mode includes an HS signaling mode and the second signaling mode includes a PWM signaling mode. In some examples, the memory includes non-volatile memory. In some examples, the parameter includes a DC gain, a CTLE peak, a DFE offset, an Rx CDR, or any combination thereof.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

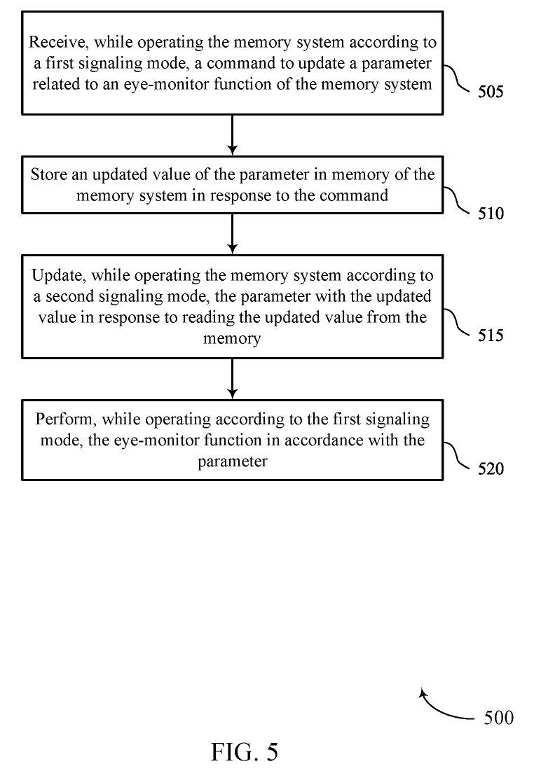

FIG. 5 shows a flowchart illustrating a method 500 that supports updating eye-monitor related parameters for a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include receiving, while operating the memory system according to a first signaling mode, a command to update a parameter related to an eye-monitor function of the memory system. In some examples, aspects of the operations of 505 may be performed by a command component 425 as described with reference to FIG. 4.

At 510, the method may include storing an updated value of the parameter in memory of the memory system in response to the command. In some examples, aspects of the operations of 510 may be performed by a storage component 430 as described with reference to FIG. 4.

At 515, the method may include updating, while operating the memory system according to a second signaling mode, the parameter with the updated value in response to reading the updated value from the memory. In some examples, aspects of the operations of 515 may be performed by a modification component 435 as described with reference to FIG. 4.

At 520, the method may include performing, while operating according to the first signaling mode, the eye-monitor function in accordance with the parameter. In some examples, aspects of the operations of 520 may be performed by an eye-monitor component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving, while operating the memory system according to a first signaling mode, a command to update a parameter related to an eye-monitor function of the memory system; storing an updated value of the parameter in memory of the memory system in response to the command; updating, while operating the memory system according to a second signaling mode, the parameter with the updated value in response to reading the updated value from the memory; and performing, while operating according to the first signaling mode, the eye-monitor function in accordance with the parameter.

Aspect 2: The method, apparatus, or non-transitory computer-readable medium of aspect 1, further including operations, features, circuitry, logic, means, or instructions, or any combination thereof for receiving, after performing the eye-monitor function and while operating the memory system according to the first signaling mode, a second command to reset the parameter related to the eye-monitor function of the memory system to a first value from the updated value.

Aspect 3: The method, apparatus, or non-transitory computer-readable medium of aspect 2, further including operations, features, circuitry, logic, means, or instructions, or any combination thereof for storing a reset value of the parameter in the memory of the memory system in response to the second command.

Aspect 4: The method, apparatus, or non-transitory computer-readable medium of aspect 3, further including operations, features, circuitry, logic, means, or instructions, or any combination thereof for updating, while operating the memory system according to the second signaling mode, the parameter with the first value in response to reading the reset value from the memory.

Aspect 5: The method, apparatus, or non-transitory computer-readable medium of any of aspects 3 through 4, where the reset value includes a value of zero.

Aspect 6: The method, apparatus, or non-transitory computer-readable medium of any of aspects 1 through 5, further including operations, features, circuitry, logic, means, or instructions, or any combination thereof for entering the second signaling mode as part of a boot procedure at the memory system, where the parameter is updated in response to entering the second signaling mode.

Aspect 7: The method, apparatus, or non-transitory computer-readable medium of any of aspects 1 through 6, further including operations, features, circuitry, logic, means, or instructions, or any combination thereof for exiting the second signaling mode, where the command is received in response to exiting the second signaling mode.

Aspect 8: The method, apparatus, or non-transitory computer-readable medium of any of aspects 1 through 7, further including operations, features, circuitry, logic, means, or instructions, or any combination thereof for transmitting a message verifying that the updated value of the parameter was stored in the memory of the memory system in response to storing the updated value of the parameter in the memory of the memory system.

Aspect 9: The method, apparatus, or non-transitory computer-readable medium of any of aspects 1 through 8, where the first signaling mode includes an HS signaling mode and the second signaling mode includes a PWM signaling mode.

Aspect 10: The method, apparatus, or non-transitory computer-readable medium of any of aspects 1 through 9, where the memory includes non-volatile memory.

Aspect 11: The method, apparatus, or non-transitory computer-readable medium of any of aspects 1 through 10, where the parameter includes a DC gain, a CTLE peak, a DFE offset, an Rx CDR, or any combination thereof.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
receive, while operating the memory system according to a first signaling mode, a command to update a parameter related to an eye-monitor function of the memory system;
store an updated value of the parameter in memory of the memory system in response to the command;
update, while operating the memory system according to a second signaling mode, the parameter with the updated value in response to reading the updated value from the memory; and
perform, while operating according to the first signaling mode, the eye-monitor function in accordance with the parameter.

2. The memory system of claim 1, wherein the processing circuitry is further configured to cause the memory system to:
receive, after performing the eye-monitor function and while operating the memory system according to the first signaling mode, a second command to reset the parameter related to the eye-monitor function of the memory system to a first value from the updated value.

3. The memory system of claim 2, wherein the processing circuitry is further configured to cause the memory system to:
store a reset value of the parameter in the memory of the memory system in response to the second command.

4. The memory system of claim 3, wherein the processing circuitry is further configured to cause the memory system to:
update, while operating the memory system according to the second signaling mode, the parameter with the first value in response to reading the reset value from the memory.

5. The memory system of claim 3, wherein the reset value comprises a value of zero.

6. The memory system of claim 1, wherein the processing circuitry is further configured to cause the memory system to:
enter the second signaling mode as part of a boot procedure at the memory system, wherein the parameter is updated in response to entering the second signaling mode.

7. The memory system of claim 1, wherein the processing circuitry is further configured to cause the memory system to:
exit the second signaling mode, wherein the command is received in response to exiting the second signaling mode.

8. The memory system of claim 1, wherein the processing circuitry is further configured to cause the memory system to:
transmit a message verifying that the updated value of the parameter was stored in the memory of the memory system in response to storing the updated value of the parameter in the memory of the memory system.

9. The memory system of claim 1, wherein the first signaling mode comprises a high speed signaling mode and the second signaling mode comprises a pulse width modulation signaling mode.

10. The memory system of claim 1, wherein:
the memory comprises non-volatile memory.

11. The memory system of claim 1, wherein the parameter comprises a direct current gain, a continuous time linear equalization peak, a decision feedback equalization offset, a receiver clock and data recovery, or any combination thereof.

12. A non-transitory computer-readable medium storing code comprising instructions which, when executed by processing circuitry of a memory system, cause the memory system to:
receive, while operating the memory system according to a first signaling mode, a command to update a parameter related to an eye-monitor function of the memory system;
store an updated value of the parameter in memory of the memory system in response to the command;
update, while operating the memory system according to a second signaling mode, the parameter with the updated value in response to reading the updated value from the memory; and
perform, while operating according to the first signaling mode, the eye-monitor function in accordance with the parameter.

13. The non-transitory computer-readable medium of claim 12, wherein the instructions, when executed by the processing circuitry of the memory system, further cause the memory system to:
receive, after performing the eye-monitor function and while operating the memory system according to the first signaling mode, a second command to reset the parameter related to the eye-monitor function of the memory system to a first value from the updated value.

14. The non-transitory computer-readable medium of claim 13, wherein the instructions, when executed by the processing circuitry of the memory system, further cause the memory system to:
store a reset value of the parameter in the memory of the memory system in response to the second command.

15. The non-transitory computer-readable medium of claim 14, wherein the instructions, when executed by the processing circuitry of the memory system, further cause the memory system to:
update, while operating the memory system according to the second signaling mode, the parameter with the first value in response to reading the reset value from the memory.

16. The non-transitory computer-readable medium of claim 14, wherein the reset value comprises a value of zero.

17. The non-transitory computer-readable medium of claim 12, wherein the instructions, when executed by the processing circuitry of the memory system, further cause the memory system to:
enter the second signaling mode as part of a boot procedure at the memory system, wherein the parameter is updated in response to entering the second signaling mode.

18. The non-transitory computer-readable medium of claim 12, wherein the instructions, when executed by the processing circuitry of the memory system, further cause the memory system to:
exit the second signaling mode, wherein the command is received in response to exiting the second signaling mode.

19. The non-transitory computer-readable medium of claim 12, wherein the instructions, when executed by the processing circuitry of the memory system, further cause the memory system to:
transmit a message verifying that the updated value of the parameter was stored in the memory of the memory system in response to storing the updated value of the parameter in the memory of the memory system.

20. A method by a memory system, comprising:
receiving, while operating the memory system according to a first signaling mode, a command to update a parameter related to an eye-monitor function of the memory system;
storing an updated value of the parameter in memory of the memory system in response to the command;
updating, while operating the memory system according to a second signaling mode, the parameter with the updated value in response to reading the updated value from the memory; and
performing, while operating according to the first signaling mode, the eye-monitor function in accordance with the parameter.
